(19) United States
(12) Patent Application Publication
(10) Pub. No.: US 2004/0024573 A1
(43) Pub. Date: Feb. 5, 2004

(54) Method, system, and program for rendering information about network components

(75) Inventors: Jeffrey W. Allen, Denver, CO (US); Jeffrey A. Hanson, Westminster, CO (US); Peter W. Madany, Fremont, CA (US); Jeffrey Lawrence Sokolov, Lexington, MA (US)

Correspondence Address: David W. Victor, KONRAD RAYNES VICTOR & MANN LLP, 315 S. Beverly Drive, Suite 210, Beverly Hills, CA, 90212, US

(73) Assignee: Sun Microsystems, Inc.

(21) Appl. No.: 10/208,958

(22) Filed: Jul. 31, 2002

(51) Int. Cl. H03F 1/26; G06F 15/00; H04B 15/00

(52) U.S. Cl. 702/189

(57) ABSTRACT

Provided are a method, system, and program for providing information on components within a network. A user selected host and storage in the network is received and switches are determined to which the selected host and storage connect. Images representing the selected host and storage and all determined switches and connections therebetween are then rendered.

### BACKGROUND OF THE INVENTION

1. Field of the Invention

The present invention relates to a method, system, and program for rendering information about network components.

2. Description of the Related Art

A storage area network (SAN) comprises a network linking one or more servers to one or more storage systems. Each storage system could comprise a Redundant Array of Independent Disks (RAID) array, tape backup, tape library, CD-ROM library, or JBOD (Just a Bunch of Disks) components. One common protocol for enabling communication among the various SAN devices is the Fibre Channel protocol, which uses optical fibers or copper wires to connect devices and provide high bandwidth communication between the devices. The Fibre Channel protocol defines a fabric topology. A fabric includes one or more interconnected switches, each switch having multiple ports. A fiber link may connect ports on a device to ports on a switch, where a device connected to a switch in a fabric can communicate with all other ports attached to any switch in the fabric.

During SAN operations, information on various devices in one or more fabrics in a SAN may be gathered. The information may concern devices from different vendors. There is a need in the art for improved techniques for managing information gathered on the different components in a SAN and making such information available to the SAN administrator and others in a normalized format.

### SUMMARY OF THE DESCRIBED IMPLEMENTATIONS

Provided are a method, system, and program for providing information on components within a network. A user selected host and storage in the network is received and switches are determined to which the selected host and storage connect. Images representing the selected host and storage and all determined switches and connections therebetween are then rendered.

In further implementations, a determination is made of at least one zone and the images representing components in the determined at least one zone are rendered in a different manner than images representing components not in the determined at least one zone.

Still further, determining the switches may comprise determining all switches to which the selected host and storage directly and indirectly connect, and wherein the switches directly and indirectly attached and connections thereto are rendered.

In certain implementations, the rendered images representing the selected host, storage, and all determined switches connected to the host and storage may not show any common switch providing an interconnection between the host and storage. Additionally, the rendered images may show a switch providing a physical connection between the selected host and storage and the rendered images may not show any interconnection between the host and storage by representing the physical connection between the selected host and storage as included in a zone inaccessible to the selected host.

Described implementations provide improved techniques for determining and rendering information about network components

### BRIEF DESCRIPTION OF THE DRAWINGS

Referring now to the drawings in which like reference numbers represent corresponding parts throughout:

FIG. 1 illustrates an arrangement of network components in a manner known in the art;

FIG. 2 illustrates program components in a network management application in accordance with implementations of the invention;

FIG. 3 illustrates a topology of objects providing information on network components in accordance with implementations of the invention;

FIGS. 4, 5, 6, 7, and 8 illustrate contents of data structures providing information on network components in accordance with implementations of the invention;

FIG. 9 illustrates data structures used to generate topology objects in accordance with implementations of the invention;

FIGS. 10, 11, 12, 13, 14, 15, 16, and 17 illustrate operations performed to generate the topology of objects shown in FIG. 3 in accordance with implementations of the invention;

FIG. 18 illustrates an example of output generated from information maintained in the objects providing information on network components in accordance with implementations of the invention; and

FIG. 19 illustrates operations performed to process the objects providing information on network components to generate the output shown in FIG. 17 in accordance with implementations of the invention;

FIGS. 20, 21, and 22 illustrate user interface panels displayed to enable a user to render images representing connections between a selected host and storage components in accordance with implementations of the invention;

FIGS. 23a, 23b, and 24 illustrate logic to render the images representing a selected host and storage and the switches directly and indirectly connected to the selected host and storage in accordance with implementations of the invention;

FIGS. 25 and 26 illustrate examples of a network topology rendered according to the logic of FIGS. 23 and 24 in accordance with implementations of the invention; and

FIG. 27 illustrates a computer architecture that may be used to implement network devices, such as the SAN manager system, hosts, storages, switches, etc.

### DETAILED DESCRIPTION OF THE PREFERRED EMBODIMENTS

In the following description, reference is made to the accompanying drawings which form a part hereof and which illustrate several embodiments of the present invention. It is understood that other embodiments may be utilized and structural and operational changes may be made without departing from the scope of the present invention.

### Representing Network Components in a Node Topology

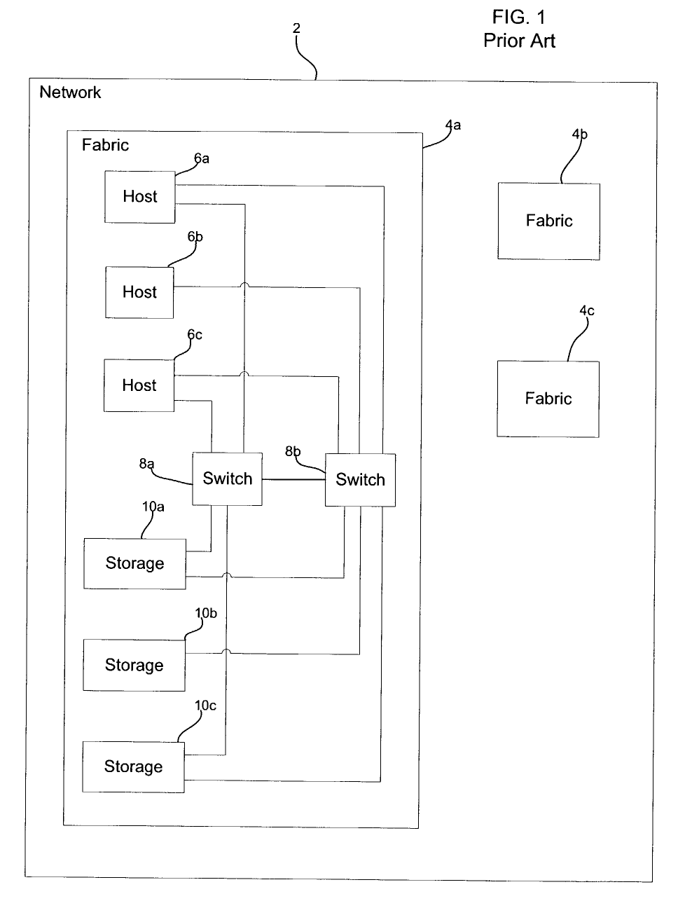

FIG. 1 illustrates an example of a network 2, such as a SAN, comprised of multiple fabrics 4a, 4b, 4c, where each fabric includes multiple interconnected devices, also referred to as components, such that the switches in one fabric do not connect to any of the devices in another fabric. As shown in fabric 4a, a fabric includes hosts 6a, 6b, 6c, switches 8a, 8b, and storages 10a, 10b, 10c, where each device in the fabric is connected to one or more other devices in the fabric. The hosts 6a, 6b, 6c, switches 8a, 8b, and storages 10a, 10b, 10c would further each include one or more ports (not shown) to provide one or more connections with another component. The hosts 6a, 6b, 6c include host bus adaptor (HBA) cards (not shown) that include the host ports to connect to switch ports. Further switch 8a, 8b ports may be included in zones, such that any device attached to a switch port in one particular zone can only communicate with devices attached to switch ports in the same zone. Still further, a host may include multiple ports and have different ports connected to different switches, where the switches are not in any way interconnected. In such an arrangement, the host connected to such switches that are not connected is connected to different fabrics. The switches 8a, 8b may be connected via an interswitch link, such as shown in FIG. 1, or not connected.

The hosts 6a, 6b, 6c may comprise any computing device known in the art, such as a server class machine, workstation, storage host, host cluster, etc., having adaptor cards with ports to connect to one switch port in switches 8a, 8b. The switches 8a, 8b may each include multiple switch ports to interconnect different devices in a fabric, wherein the devices may be connected in a network, such as a SAN, Local Area Network (LAN), Wide Area Network (WAN), etc. The storages 10a, 10b, 10c may comprise any storage system known in the art which has compatible ports, such as a storage array, e.g., a storage subsystem, a subsystem cluster, Just a Bunch of Disks (JBOD), Redundant Array of Independent Disks (RAID), Direct Access Storage Device (DASD), etc., tape drive, tape library, disk drive, optical disk drive, etc. The ports within the hosts 6a, 6b, 6c and storages 10a, 10b, 10c may comprise NxPorts, or any other ports known in the art. The network 2 or SAN may further include direct attached storage (DAS) devices that connect directly to another host or device other than a switch and orphan devices not connected to any other component.

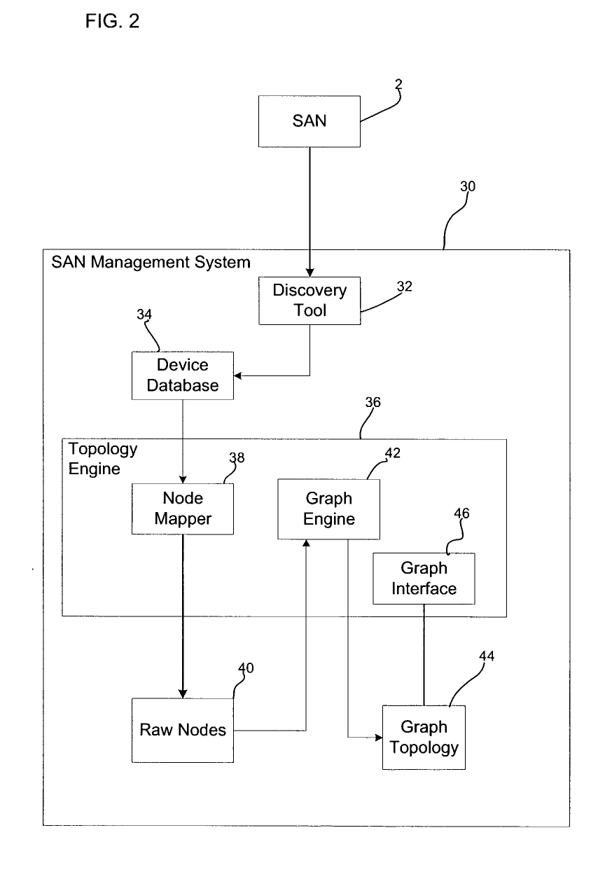

FIG. 2 illustrates a SAN management system 30 used by a network administrator, where the system 30 may be coupled to the SAN 2 or implemented in a SAN component. The SAN management system 30 includes a discovery tool 32 program that mines device information from the SAN 2 and populates a device database 34 with the mined information that stores information on each of the components of the SAN 2, where a component comprises a logical or physical device, e.g., hosts 6a, 6b, 6c, switches 8a, 8b, storages 10a, 10b, 10c, adaptors with the devices, ports, logical storage, zones, fabrics, etc. In certain implementations, the device database 34 may comprise a SAN domain model device information database. Thus, each component discovered by the discovery tool 32 may contain additional discovered components. For instance a discovered host 6a, 6b, 6c may include a discovered host bus adaptor (HBA), and the discovered HBA may include discovered ports; a discovered zone component may include device components and subcomponents; a discovered fabric may include numerous discoverable devices and subcomponents thereof. The discovery tool 32 may comprise multiple programs, tools or Application Programming Interfaces (APIs) provided by different device vendors whose devices are included in the SAN 2. Alternatively, the discovery tool 32 may access information from devices implementing the Common Information Model (CIM) protocol to exchange device information. However, those skilled in the art will appreciate that any device management interface may be used to access device information from the SAN components. The device database 34 stores the discovered device data.

A topology engine program 36 includes program components 38, 42, and 46 to process the device information in the device database 34. The topology engine 36 includes a node mapper 38 program that transforms the data in the device database 34, that may be gathered by discovery tools from different vendors, into a plurality of raw nodes 40 in a common format, where each raw node maintains various device information. A graph engine 42 program processes the raw nodes 40 and generates a graph topology 44 including graph nodes providing interrelated data structures that store the device information. A graph interface 46 provides methods, such as program functions and/or graphical user interface (GUI) controls, to allow a user to traverse the graph topology 44 to access information on the connection and arrangement of devices in the SAN 2 and render graphical representations of the SAN components and their physical and logical interrelationship. In alternative implementations, the program components 38, 42, and 46 of the topology engine 36 may comprise separate applications, or some of the components 38, 42, and 46 may be external to the topology engine 36.

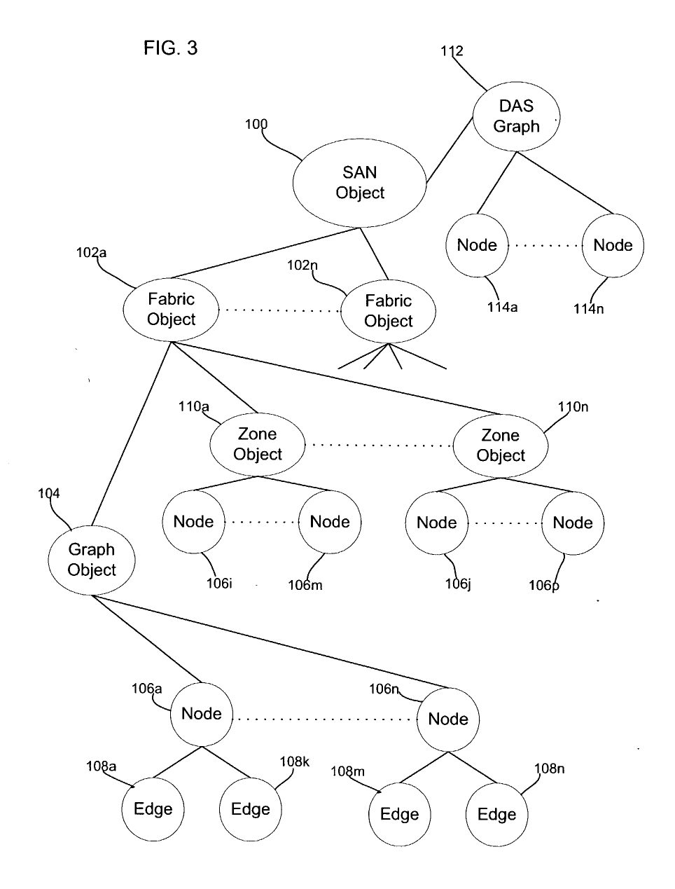

FIG. 3 illustrates one implementation of the graph topology 44 data model in accordance with implementations of the invention. A SAN object 100 provides information on the SAN 2 and references one or more fabric objects 102a . . . 102n, where n is the number of discovered fabrics 4a, 4b, 4c (FIG. 1) in the SAN. Any variable used herein to represent a number of unknown value, e.g., m, n, p, k, q, r, etc., represents any integer value, and where the variables may represent the same or different integer values. Each fabric 102a . . . 102n would include a reference to one graph object 104 and one or more zone objects 110a . . . 110n for each zone in the fabric 4a, 4b, 4c represented by the fabric object 102a . . . 102. If there are no zones in the fabric, then the fabric object 102a . . . 102n for such fabric would not reference any zone objects. Each graph object 104 references a plurality of graph nodes 106a . . . 106n, where there is one graph node for each discovered component in the fabric 4a, 4b, 4c represented by the fabric object 102a . . . 102n including graph object 104. As discussed, a graph node 106a . . . 106n may be provided for each component in the fabric, e.g., host 6a, 6b, 6c, switch 8a, 8b, storage 10a, 10b, 10c and separately addressable subcomponents thereof, such as ports. Each node 106a . . . 106n that represents a SAN component that physically connects to another SAN component would reference one or more input edge objects 108a, 108m and one or more output edge objects 108b, 108n providing information on a physical connection through which data flows into the SAN component and a connection through which data flows out of the SAN component, respectively. Each edge object 108a . . . 108n provides information on a connection between two SAN components and the direction of data flow therebetween, which may indicate that data flows only one way or bi-directionally. For instance, an edge object 108a . . . 108n may provide information on a connection between two ports represented by graph nodes. Each zone object 110a . . . 110n may reference graph nodes 106a . . . 106n, shown as graph nodes 106i . . . 106m and 106n . . . 106p that represent switch ports in the zone represented by the zone object 110a . . . 110n.

The topology of FIG. 3 further includes a Direct Access Storage (DAS) graph object 112 associated with the SAN object 100. The DAS graph object 112 references graph nodes 114a . . . 114n that represent directly attached components, such as hosts, host bus adaptors (HBAs), devices, and the ports within the devices that connect to other direct attached devices. The DAS ports are not within a fabric. However, a device that has a DAS port connected to a storage device that is not within a fabric may have an additional port connected to a switch port within a fabric. The storage device including the port attached to the component represented by graph nodes 114a . . . 114n may or may not be within a fabric. The DAS nodes 114a . . . 114n would reference input and output edge objects (not shown) providing information on the physical connection between DAS components.

In the above graph topology shown in FIG. 3, each of the objects may be accessible using the graph interface 46, such that information on the connection of the devices can be accessed by accessing the objects in the topology shown in FIG. 3. Further, upon accessing any object in the topology, any of the related objects referenced by such accessed object may be accessed through such references to access information on the related item. For instance, upon using the graph interface 46 to access information on a particular fabric 4a, 4b, 4c from the corresponding fabric object 102a . . . 102n, the physical graph object 104 for the accessed fabric object 102a may be accessed to determine information on the components in the fabric represented by the graph nodes 106a . . . 106n referenced by the physical graph object 104. Information on the connection between the nodes 106a . . . 106n may be accessed from the edge objects 108a . . . 108n. Further, information on the zones in a fabric 4a, 4b, 4c represented by fabric object 102a may be determined from the zone objects 110a . . . 110 referenced by the fabric object 102.

With the graph topology of FIG. 3, all the graph nodes may have the same data structure format even though the graph nodes may represent different types of devices and devices from different vendors. Further, the graph nodes 106a . . . 106n may represent a contained component that is a subcomponent of a larger composite component, i.e., a port in an adaptor (e.g., HBA) or switch. Each of the SAN 100, fabric 102a . . . 102n, physical graph 104, node 106a . . . 106n, and zone 110a . . . 110n objects provide information on the object type that would be useful to an administrator of the SAN 2. For instance, the zone objects 110a . . . 110n may include information identifying the zone, its security level, etc.

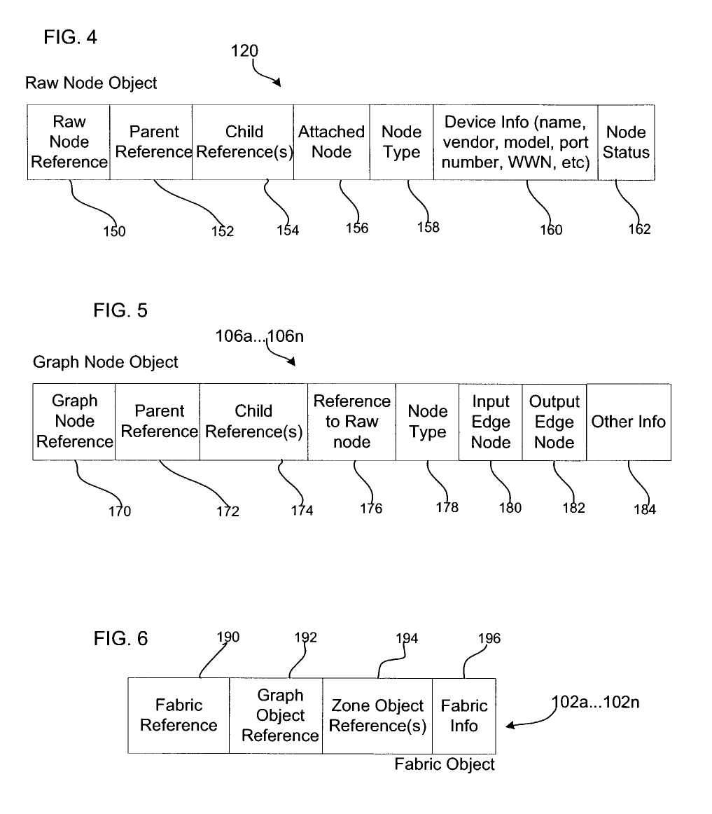

FIG. 4 illustrates the information maintained in the raw node objects 120 generated by the node mapper 38.

Raw Node Reference 150: uniquely identifies the raw node.

Parent Reference 152: references a parent raw node representing a composite SAN component physically or logically containing the component represented by the current raw node.

Child References 154: comprises one or more references to raw nodes that represent SAN components physically or logically contained within the composite SAN component represented by the current raw node, i.e., child raw nodes, if there are such components contained within the current component.

Attached Node 156: if the current raw node 150 represents a port component, then the attached node 156 may represent the port(s), if any, to which the current node connects in the SAN 2.

Node Type 158: indicates the type of component represented by the raw node, i.e., storage system, switch, switch port, port, zone, HBA, fabric, etc. Device Information 160: provides additional information on the component represented by the raw node, such as the name of the device, vendor, model, port number, World Wide Name (WWN), etc.

Node Status 162: Indicates the current state of the device or component represented by the node, such as available, failed, unavailable, etc.

FIG. 5 illustrates fields in the graph nodes 106a . . . 106n that are generated from the raw nodes for the SAN components. The graph nodes 106a . . . 106n include:

Graph Node Reference 170: uniquely identifies the graph node.

Parent Reference 172: references a parent graph node for the graph node, if there is such a parent, where the parent graph node represents a composite SAN component that physically or logically contains the SAN component represented by the current graph node.

Child References 174: comprises one or more references to graph nodes that represent SAN components physically or logically contained within the composite SAN component represented by the current graph node, i.e., child graph nodes, if there are such components contained within the current component.

Reference to Raw Node 176: provides a reference to the raw node that represents the same SAN component represented by the current graph node, where the graph nodes are generated from the raw nodes.

Node Type 178: indicates the type of component represented by the graph node, i.e., storage system, switch, switch port, zone, HBA, fabric, etc.

Input Edge Object 180: references an edge object 108a . . . 108n indicating a physical connection to another SAN component where data flows from the other SAN component indicated in the input edge object 180 to the component represented by the graph node, if there is such a physically connected SAN component.

Output Edge Object 182: references an edge object 108a . . . 108n indicating a physical connection to another SAN component where data flows from the SAN component represented by the graph node to the other SAN component indicated in the input edge object 180, if there is such a physically connected SAN component.

Other Information 184: provides additional information on the SAN component represented by the graph node, such as the name of the device, vendor, model, port number, World Wide Name (WWN), etc. Such information, if provided, may comprise a subset or all of the device information 160 included in the raw node 120 (FIG. 4).

FIG. 6 illustrates the fields maintained in the fabric objects 102a . . . 102n, including:

Fabric Reference 190: uniquely identifies the fabric object.

Reference to Graph Object 192: references the graph object 104 for the fabric represented by the fabric object that, in turn, references graph nodes 106a . . . 106n representing SAN components in the fabric.

Zone Object Reference(s) 194: references zero or more zone objects that each represent a zone included in the fabric.

Fabric Information 196: this is an optional one or more fields that may provide additional information on the fabric.

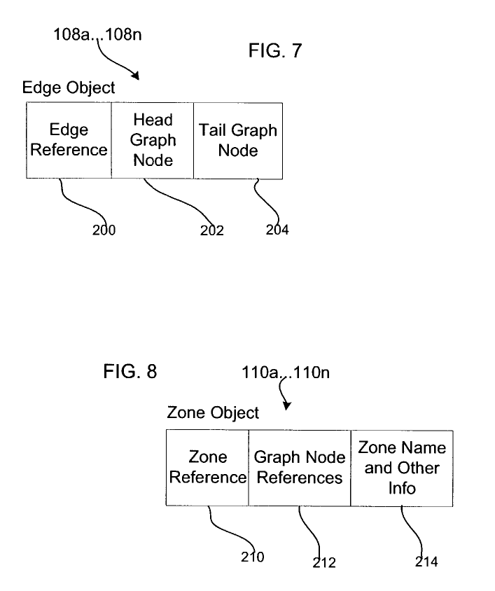

FIG. 7 illustrates fields included in the edge objects 108a . . . 108n that represent a physical connection and direction of data flow between two SAN ports represented by two or more graph nodes 106a . . . 106n, including:

Edge Reference 200: uniquely identifies the edge object 108a . . . 108n in the graph topology 44.

Head Graph Node 202: provides a reference to the graph node representing one SAN port physically connected to another SAN port.

Tail Graph Node 204: provides a reference to the graph node representing the SAN port physically connected to the port represented by the head graph node 202. Nodes are designated head or tail to indicate the direction of data flow, where data flows from the port represented by the head graph node to the port represented by the tail graph node. Two edge objects may be used to represent bidirectional communication of data between two ports represented by two nodes node.

FIG. 8 illustrates fields included in the zone objects 110a . . . 110n providing references to switch ports in a zone of a fabric, including:

Zone Reference 210: uniquely identifies the zone object in the graph topology 44.

Graph Node References 212: provides references to the one or more graph nodes representing switch ports included in the zone.

Zone Name and Other Info 214: Provides a name or identifier of the zone in the fabric and may include additional information, such as a reference to the fabric object 102a . . . 102n containing the zone.

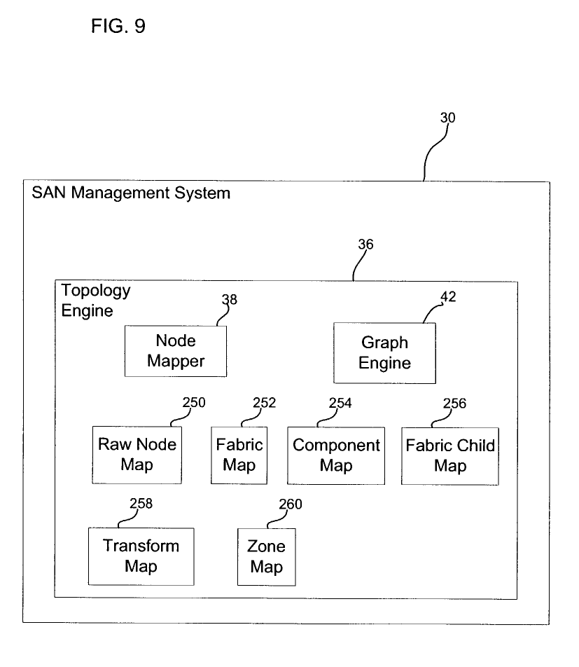

FIG. 9 illustrates data structures used by the topology engine 36 components to generate the graph topology 44. The node mapper 38 generates a raw node map 250 that is used by the graph engine 42 to generate the graph topology 44. The graph engine 42 generates a fabric map 252, composite map 254, fabric child map 256, transform map 258, and zone map 260 that are used, in the manner described below, when generating the graph topology 44. These maps 250, 252, 254, 256, 258, and 260 may be maintained in a memory area used by the topology engine 36.

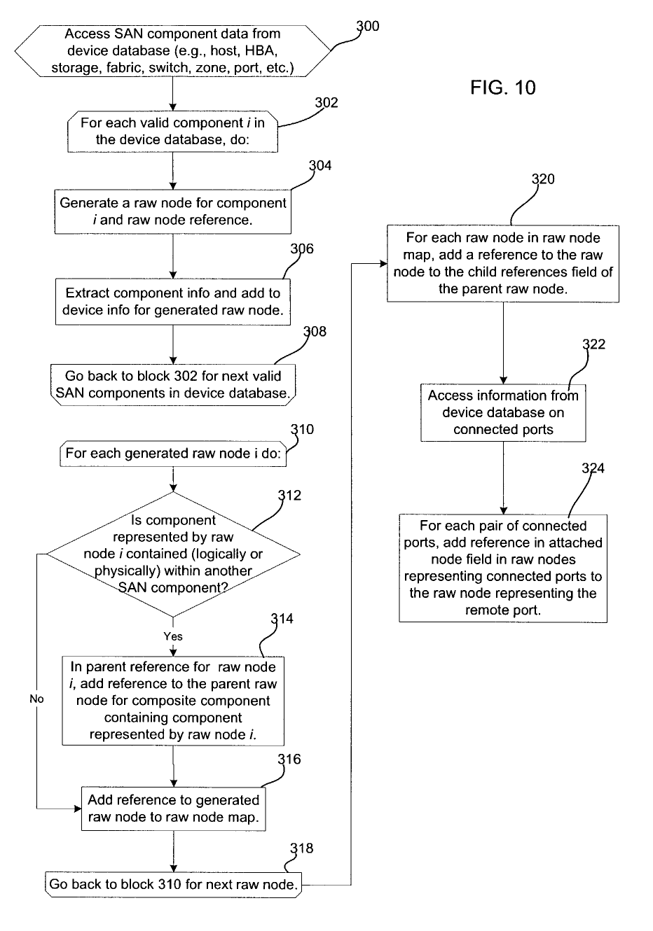

FIG. 10 illustrates logic implemented in the node mapper 38 to generate raw nodes from the SAN component information maintained in the device database 34. Control begins at block 300 with the node mapper 38 accessing the SAN component data from the device database 34 on SAN components, including hosts, host bus adaptors (HBAs), storage systems, fabrics, switches, zones, ports, etc. For each valid component i indicated in the device database, the node mapper 38 performs a loop between blocks 302 and 308, where a valid component comprises a component to be represented in the graph topology 44, such as hosts, host bus adaptors (HBAs), storage systems, fabrics, switches, zones, ports, etc. At block 304, the node mapper 38 generates a raw node object 120 for the component i and a raw node reference 150 for the raw node 120. Component information is extracted (at block 306) from the device database for component i and added to the device information field 160 of the generated raw node, such as component name, vendor, model, port number, World Wide Name (WWN), etc.

From block 310 through 318, the node mapper 38 performs a loop for each generated raw node. If (at block 312) the component represented by raw node i is logically or physically contained within another composite SAN component, then the node mapper 38 adds (at block 314) a reference to the parent raw node for raw node i to the parent raw node representing the composite SAN component containing the component represented by raw node i in the parent reference field 152 (FIG. 4) and adds (at block 316) the reference to the generated raw node 120 to a raw node map 250. Control then returns (at block 318) back to block 310 to process the next generated raw node 120.

After generating raw nodes for all valid components in the SAN, the node mapper 38, for each raw node indicated in the raw node map 250, adds (at block 320) a reference to the raw node in the parent reference 152 of the child raw nodes, indicated in the child references field 154. The node mapper 38 then accesses (at block 322) information from the device database 34 on the connected ports and, for each pair of connected ports, adds (at block 324) references in the attached node field 156 of the raw nodes of each connected port the reference to the raw node representing the remote port. The result of the logic of FIG. 9 is a set of raw nodes 40, one for each of certain valid SAN components indicated in the device database 34.

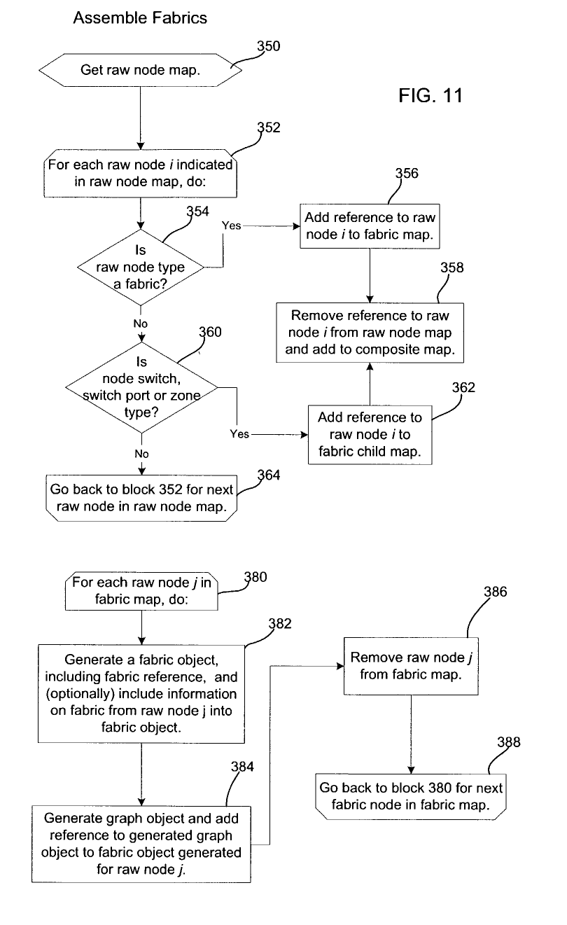

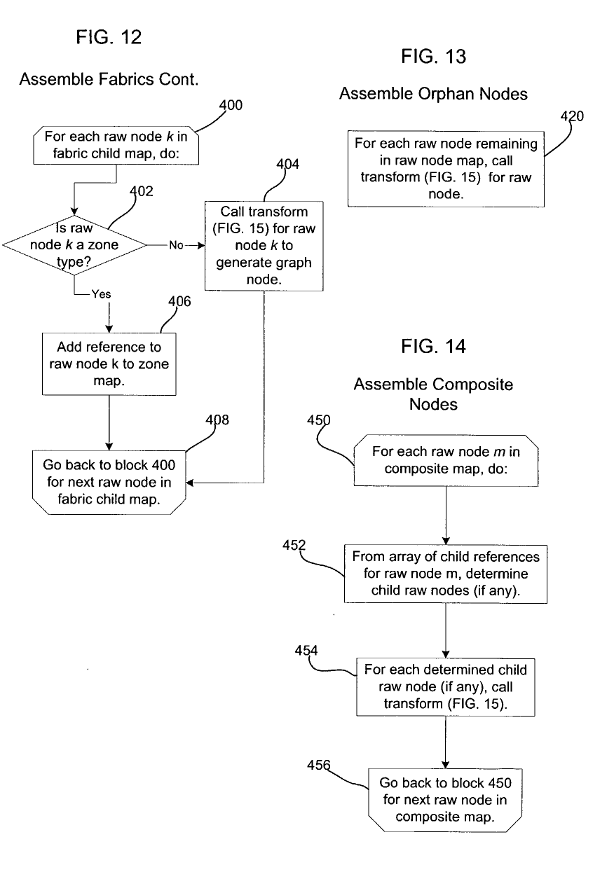

FIGS. 11-17 illustrates logic implemented in the graph engine 42 to transform the content of the raw nodes 40 into a graph topology 44 including a set of interrelated graph objects representing the SAN components, such as shown in FIG. 3. In FIGS. 11 and 12, the graph engine 42 assembles the fabric objects 102a . . . 102n representing fabric components and begins assembling the graph nodes for the children of the fabric 102a . . . 102n, such as switches, switch ports, zones. With respect to FIG. 11, the graph engine 42 gathers (at block 350) the raw nodes 40. For each raw node i indicated in the raw node map 250, a loop is performed at blocks 352 to 364. If (at block 354), the raw node i type 158) is a fabric, then a reference to raw node i is added (at block 356) to a fabric map 252 and the reference to raw node i is removed (at block 358) from the raw node map 250 and added to a composite map 254. The composite map 254 indicates raw nodes representing composite components logically or physically containing SAN components.

If (at block 354) raw node i does not represent a fabric component, but is (at block 360) of type switch, switch port or zone, then a reference to raw node i is added (at block 362) to a fabric child map 256, indicating the children of a fabric component, and the reference to raw node i is removed (at block 358) from the raw node map 250. A separate fabric child map 256 may be provided for each fabric indicated in the fabric map 252.

The graph engine 42 then performs a loop at blocks 380 through 388 to generate a fabric object 102a . . . 102n for each raw node j representing a fabric in the fabric map 252. At block 382, the graph engine 42 generates a fabric object 102a . . . 102n including a fabric reference 190 (FIG. 6), and optionally may include additional information on the fabric from the device info field 160 of raw node j. A graph object 104 is generated (at block 384) for the generated fabric object and a reference to such graph object is added to field 192 of the fabric object 102a . . . 102n generated for raw node j. The reference to the generated fabric object 102a . . . 102n is then removed (at block 386) from the fabric map 252.

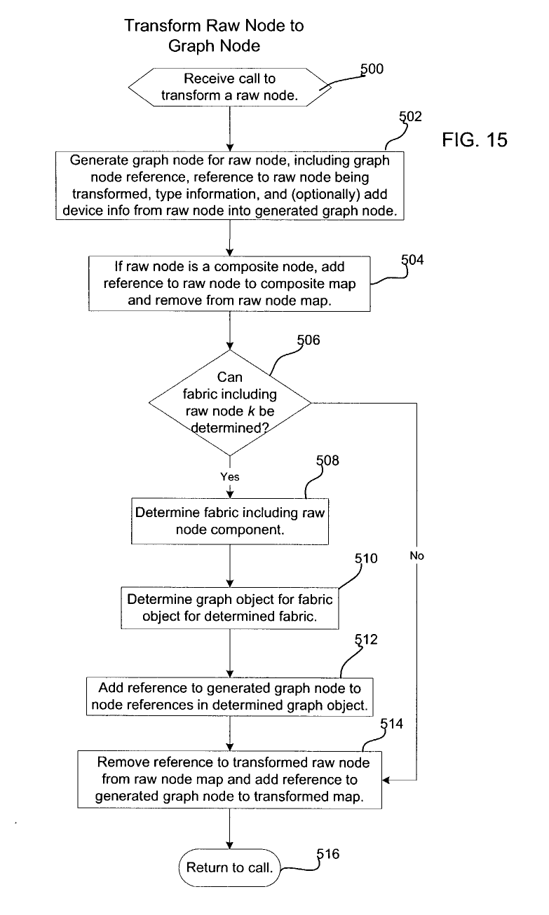

With respect to FIG. 12, the graph engine 42 performs a loop at blocks 400 through 408 for each raw node k in the fabric child map 256. If (at block 402) the raw node k type 158) indicates a zone, then a reference 150 to raw node k is added (at block 406) to a zone map 260 providing a list of all raw nodes representing zones, where a different zone map 260 may be provided for each fabric to indicate the zones in that fabric. Otherwise, if the raw node k does not represent a zone, then it must represent a switch or switch port, which are the other possible children of a fabric component. If (at block 402) raw node k is not a zone, then the graph engine 42 calls the transform operation, whose logic is shown in FIG. 15 to generate a graph node 106a . . . 106n for each raw node k in the fabric child map 256 representing a switch or switch port.

FIG. 13 illustrates the operations the graph engine 42 performs to call (at block 420) the transform operation, represented in FIG. 15, to generate a graph node 106a . . . 106n for all raw nodes remaining in the raw node map 250 that represent possible orphan components, i.e., SAN components not attached to another component, in either a fabric or Direct Attached Storage (DAS) arrangement. These generated graph nodes may later be associated with a fabric object 102a . . . 102n or DAS graph 112 upon discovering a connection from the component represented by the graph node generated at block 420 to a SAN component represented by a graph node 106a . . . 106n associated with a graph object 104 or component represented by a graph node 114a . . . 114n associated with a DAS graph 112.

FIG. 14 illustrates operations the graph engine 42 performs to process raw nodes representing composite SAN components in the composite map 254 to generate graph nodes 106a . . . 106n for the components contained in the composite SAN components. A loop is performed at blocks 450 through 456 for each raw node m indicated in the composite map 254. At block 452 a determination is made of all child raw nodes, if any, indicated in the child references 154 (FIG. 4) of raw node m. The graph engine 42 calls the transform operation, represented in FIG. 15, to generate a graph node 106a . . . 106n for each determined child raw node. Note that a component that is contained in a composite component may itself also contain components, such as a host bus adaptor (HBA) that is both contained in a host system and contains port components.

FIG. 15 illustrates the operations performed by the transform operation that the graph engine 42 calls to transform a raw node representing a SAN component into a graph node. Upon receiving (at block 500) the transform call to transform a raw node, a graph node 106a . . . 106n is generated (at block 502) for the raw node including a graph node reference 170 (FIG. 5), a reference 176 to the raw node from which the graph node is being generated, type information in field 178, and optionally may include additional device information from field 160 in the raw node being transformed. If the raw node being transformed comprises a composite node, i.e., is a SAN component logically or physically containing other contents, i.e., references raw nodes in the child references field 154, then a reference to the raw node being transformed is added (at block 504) to the composite map 254 (to allow for transformation of the contained components during the assemble composites phase shown in FIG. 14) and removed from the raw node map 250. If (at block 506) the fabric including the SAN component represented by the raw node can be determined, assuming the raw node is contained within a SAN fabric, then the fabric including the raw node is determined (at block 508) and the graph object 104 indicated in the graph object reference field 192 (FIG. 6) is determined (at block 510). The graph engine 42 would then add (at block 512) a reference to the generated graph node 106a . . . 106n, to the graph node 104. The reference to the transformed raw node is removed from the raw node map 250 and a reference to the generated graph node 106a . . . 106n is added to the transform map 258. Control then returns (at block 516) to the caller that initiated the transform operation shown in FIG. 15.

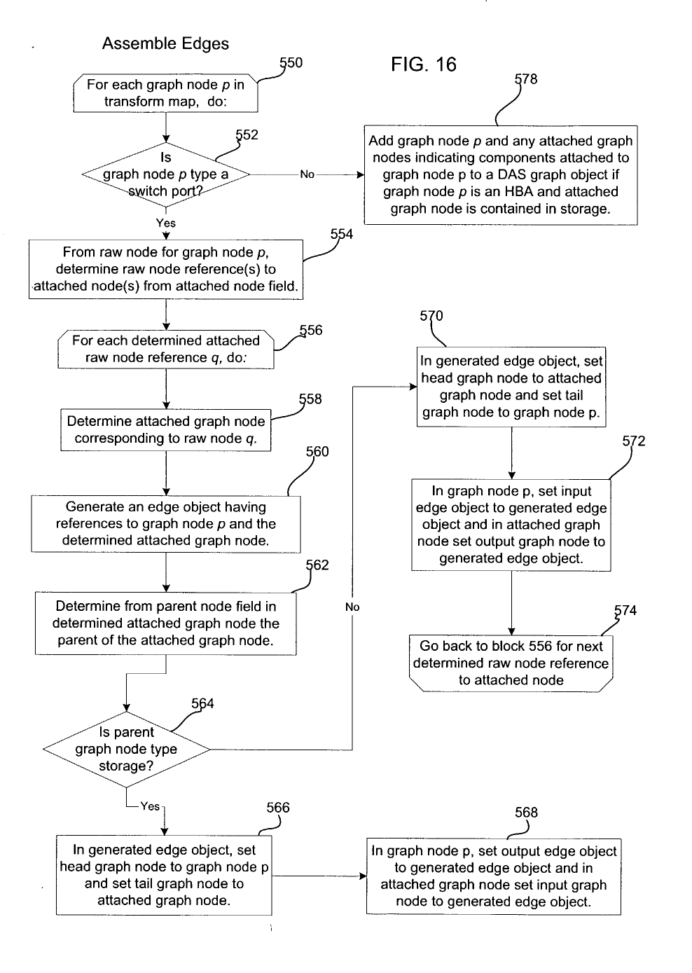

FIG. 16 illustrates operations the graph engine 42 performs to assemble edge objects 108a . . . 108n providing information on physical connections of SAN components represented by graph nodes 106a . . . 106n. A loop is performed from blocks 550 through 576 for each graph nodep indicated in the transform map 258. If (at block 552) the graph node p type, indicated in field 178, is a switch port, then from the raw node for graph node p, indicated in raw node reference field 176 of the graph node 106a . . . 106n, the graph engine 42 determines the one or more raw node references to SAN components represented by the attached graph nodes indicated in the attached node field 156 (FIG. 4). A nested loop is then performed at blocks 556 through 576 for each determined attached raw node reference q representing a component attached to the component represented by graph nodep. At block 558, the graph engine 42 determines the attached graph node 106a . . . 106n generated from the raw node q, which would be the graph node 106a . . . 106n including the reference to raw node q in reference field 176 (FIG. 5). An edge object 108a . . . 108n is generated (at block 560) having references to graph node p and the determined attached graph node in fields 202 and 204 (FIG. 7).

The graph engine 42 then determines (at block 562) from the parent reference 172 (FIG. 5) the parent of the determined attached graph node, which may comprise a reference to another graph node 106a . . . 106n. If (at block 564) the parent graph node type, indicated in field 178), is a storage system or device, then the data flows from graph node p to the determined attached graph node. In such case, the graph engine 42 sets (at block 566) in the generated edge object the head graph node 202 to graph node p and the tail graph node 204 to the attached graph node. Further, in graph node p, the output edge object 182 is set (at block 568) to the generated edge object and in the attached graph node, the input edge object 180 is set to the generated edge object. Otherwise, if (at block 564) the parent graph node type is not a storage system, then data flows from the determined attached graph node to graph node p. In such case, the graph engine 42 sets (at block 570) in the generated edge object the head graph node 202 to the attached graph node and the tail graph node 204 to graph node p. Further, in graph node p, the input edge object 180 is set (at block 572) to the generated edge object and in the attached graph node, the output edge object 182 is set to the generated edge object.

If (at block 552) the graph node p is not a switch port, then the graph node 42 would add (at block 578) the graph node p to a Direct Attached Storage (DAS) graph 112 (FIG. 3) if the graph node p is a host bus adaptor (HBA) and the attached SAN component represented by an attached graph node is contained in a storage device, indicating that graph node p represents a host port directly connected to a storage system.

One result of the logic of FIG. 16 is that graph nodes are generated for any SAN component logically or physically contained within a composite SAN component, whether the composite SAN component is attached to a fabric port or a DAS.

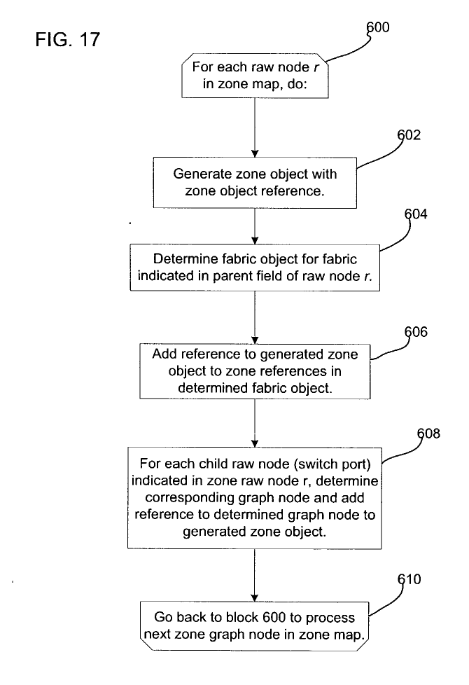

FIG. 17 illustrates operations performed by the graph engine 42 to generate zone objects 110a . . . 110n that reference graph nodes 106a . . . 106n representing SAN components that are contained within zones. A loop is performed for each raw node r in the zone map 260 from blocks 600 through 610. At block 602, the graph engine 42 generates a zone object 110a . . . 110n that includes a zone reference 210 (FIG. 8). A determination is made (at block 604) of the fabric object 102a . . . 102n representing the fabric indicated in the parent field of raw node r, because the parent of a zone is a fabric. The graph engine 42 then adds (at block 606) a reference to the generated zone object 110a . . . 110n in the zone object references field 194 of the determined fabric object 102a . . . 102n. For each child raw node indicated in the child field 154 of raw node r (which child raw nodes would represent switch ports), the graph engine 42 determines (at block 608) the corresponding graph node having the child raw node reference in field 176 (FIG. 5) and adds a reference to the determined graph node 106a . . . 106n to the generated zone object 110a . . . 110n, as that determined graph node represents a switch port within the zone.

The result of the logic of FIG. 17 is that each fabric object 102a . . . 102n representing a SAN fabric references zone objects 110a . . . 110n representing zones within that fabric, where the zone objects 110a . . . 110n reference graph nodes representing the switch ports contained within the zone.

After the graph topology 44 is generated, the content of the topology may be stored in a database or any other file or data structure in a computer readable medium. The graph topology 44 content may be refreshed whenever any change is detected to the device database 34 (FIG. 2) indicating a possible change to the SAN 2 architecture. Such a modification would trigger the node mapper 38 to regenerate the raw nodes 40, which are then provided to the graph engine 42 to process and generate the graph topology 44.

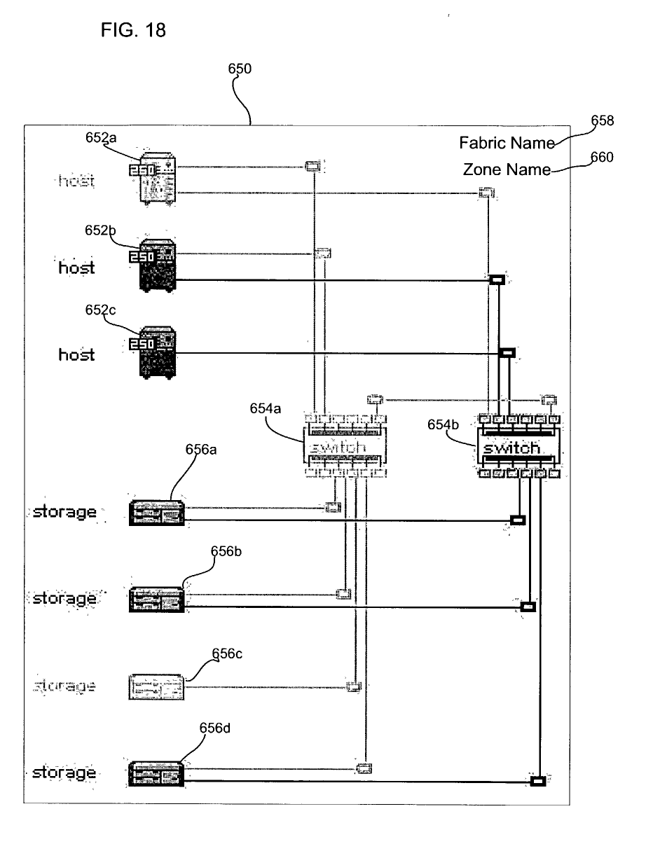

The graph interface 46 may provide a set of interfaces, such as methods or user interface controls, that allow a user to access information from any of the objects, or transfer the topology objects to obtain information on any components contained within the component represented by a particular object. For instance, FIG. 18 illustrates rendered output 650, which may be rendered on a display device or tangible medium, such as paper, that is generated by running a program that seeks to access all SAN components within a selected zone of a particular fabric, where the components in the selected zone, including switch 654b and attached hosts 652b, 652c and storage 656a, 656b, 656d, are shown darker than the components in zones other than the selected zone, including switch 654a and attached hosts 652a and storage 656c.

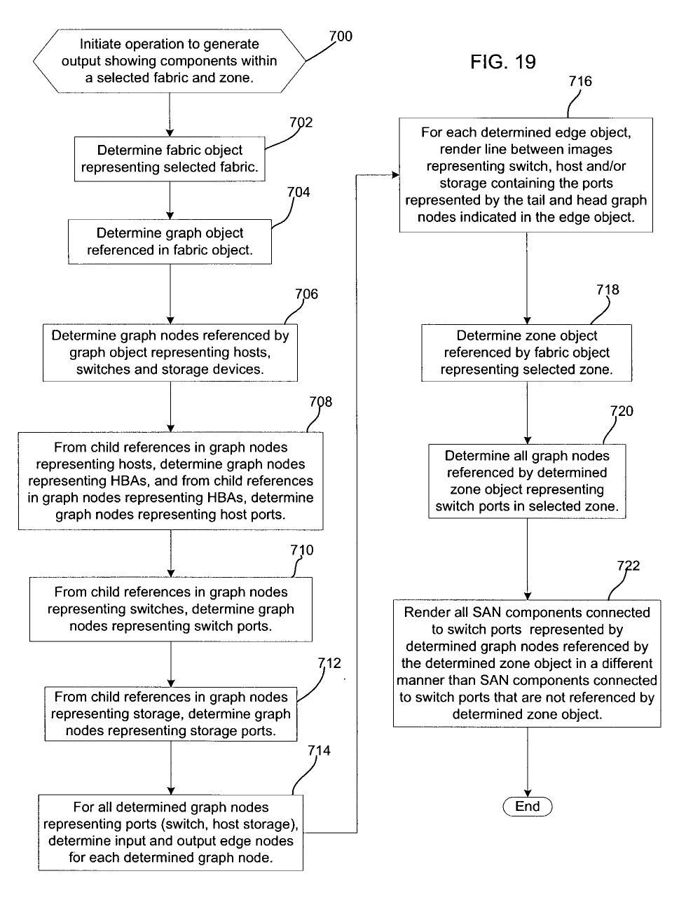

FIG. 19 illustrates operations the graph interface 46 performs with respect to the graph topology 44 to render the output 650 shown in FIG. 18. Control begins at block 700 upon initiating an operation to render output showing the host, switch, and storage components within a selected fabric and zone of the fabric. At block 700, the graph interface 46 determines (at block 702) the fabric object 102a . . . 102n representing the selected fabric and determines (at block 704) the graph object 104 referenced in field 192 (FIG. 6) of the determined fabric object 102a . . . 102n. The graph interface 46 determines (at block 706) the graph nodes 106a . . . 106n referenced in the determined graph object 104 that represent switches, hosts and storages, i.e., have type fields 178) indicating switch, host, storage. From child references 174 (FIG. 5) for graph nodes 106a . . . 106n representing hosts, a determination is made (at block 708) of graph nodes representing host bus adaptors (HBAs), i.e., of type 178 and from the child references 174 for the graph nodes representing HBAs, a determination is made of graph nodes indicated as child references 174 of HBA graph nodes, which represent host ports. At block 710, the graph interface 46 further determines from the child references for determined graph nodes representing switches, the graph nodes representing switch ports.

The graph interface 46 then determines (at block 712) edge objects 108a . . . 108n referenced in the determined graph object 104 that reference a graph node pair 202, 204 (FIG. 7) representing one determine host port and one determined switch port. For each determined edge object 108a . . . 108n, a line is then rendered (at block 716) from a host image 652a, 652b, 652c (FIG. 18) representing the host including the host port indicated in the edge object to a switch image 654a, 654b representing the switch including the switch port indicated in the edge object. The graph interface 46 further determines (at block 718), from child references in graph nodes representing storage, the graph nodes representing storage ports. A determination is then made (at block 720) of edge objects 108a . . . 108n referencing one graph node representing a determined storage port and one graph node representing a determined switch port. For each edge object determined at block 720, a line is rendered (at block 722) from a storage image 656a, 656b, 656c, 656d (FIG. 18) representing the storage including the storage port indicated in the edge object to a switch image 654a, 654b representing the switch including the switch port indicated in the edge object.

To render the zone information in the output 650 shown in FIG. 18, the graph interface 46 would determine (at block 724) the zone object 110a . . . 110n referenced by the fabric object representing the selected zone. A determination is then made (at block 726) of all graph nodes 106a . . . 106n referenced by the determined zone object 110a . . . 110n, in field 212 (FIG. 8), which represent switch ports in the selected zone. The graph interface 46 then renders (at block 728) all SAN components connected to switch ports represented by determined graph nodes 106a . . . 106n referenced by the determined zone object 110a . . . 110n in a different manner than SAN components connected to switch ports that are not referenced by the determined zone object. For instance, in the output 650 in FIG. 18, the components 652b, 652c, switch 654b, and storage 656a, 656b, 656d within the selected zone are rendered in a different manner than the components 652a, 654a, 656c outside of the selected zone. Alternatively, if no zone was selected when the graph interface 42 was invoked, then all the host, switch, and storage components in the selected fabric would be rendered in the same manner, without zone distinctions.

Numerous other algorithms and techniques may be used to traverse the nodes in the graph topology 44 to determine any level of component, e.g., port, adaptor, storage, host, switch, within any fabric in the SAN. Further, upon displaying composite components at one level, e.g., such as the hosts, switches, and storages shown in FIG. 18, selection of a particular composite component may cause the rendering of subcomponents within a selected composite component by accessing child references in the graph node representing the selected composite component. For instance, selection of a host may cause the graph interface 46 to render information on host bus adaptor (HBA) components and ports therein by traversing the children graph nodes, representing HBAs, of the graph node representing the selected composite host, and then traversing the children graph nodes of the HBA graph node representing ports.

Numerous other functions may be used to traverse the object topology to access and render information at any level of the topology.

### Outputting Information from the Node Topology

The graph interface 46 may provide a set of interfaces, such as methods or user interface controls, that allow a user to access information from any of the objects, or transfer the topology objects to obtain information on any components contained within the component represented by a particular object. For instance, FIG. 18 illustrates output 650, which may be rendered by the graph interface 46 on a display device or tangible medium, such as paper, that is attached to the SAN management system 30 in which the graph interface 46 runs. In FIG. 18, the components in the selected zone, including switch 654b and attached hosts 652b, 652c and storage 656a, 656b, 656d, are shown darker than the components in zones other than the selected zone, including switch 654a and attached hosts 652d and storage 656c. FIG. 18 further displays a fabric name 658 in which the displayed components are included and a zone name 660 indicating the zone that is displayed. FIG. 18 represents the zone having the zone name 660 by displaying those components in the zone in a darker color than components not within the zone having the zone name 660. In certain implementations, within a single fabric zone names must be unique, but the same zone name can be used in different fabrics.

FIG. 19 illustrates operations the graph interface 46 performs with respect to the graph topology 44 to render the output 650 shown in FIG. 18. Control begins at block 700 upon initiating an operation to render output showing the host, switch, and storage components within a selected fabric and zone of the fabric. At block 700, the graph interface 46 determines (at block 702) the fabric object 102a . . . 102n representing the selected fabric and determines (at block 704) the graph object 104 referenced in field 192 (FIG. 6) of the determined fabric object 102a . . . 102n. The graph interface 46 determines (at block 706) the graph nodes 106a . . . 106n referenced in the determined graph object 104 that represent switches, hosts and storages, i.e., have type fields 178 (FIG. 5) indicating switch, host, storage. From child references 174 (FIG. 5) for graph nodes 106a . . . 106n representing hosts, a determination is made (at block 708) of graph nodes representing host bus adaptors (HBAs), i.e., of type 178 HBA, and from the child references 174 for the graph nodes representing HBAs, a determination is made of graph nodes indicated as child references 174 of HBA graph nodes, which represent host ports. At block 710, the graph interface 46 further determines from the child references for the determined graph nodes representing switches, the graph nodes representing switch ports. The graph interface 46 further determines (at block 712), from child references in graph nodes representing storage, the graph nodes representing storage ports.

The graph interface 46 then determines (at block 714), for all determined graph nodes representing ports (switch, host storage), input and output edge nodes 108a . . . 108n indicated in the input 180 and output 182 (FIG. 5) edge node fields of the determined graph nodes representing the determined switch ports and host ports, where the edge objects indicate physical connections between host and switch ports. For each determined edge object 108a . . . 108n, a line is then rendered (at block 716) between images 652a, 652b, 652c, 654a, 654b, 656a, 656b, 656c, 656d (FIG. 18) representing switch, host and/or storage containing the ports represented by the tail 204 and head 202 graph nodes (FIG. 7) indicated in the determined edge objects 108a . . . 108n.

To render the zone information in the output 650 shown in FIG. 18, the graph interface 46 would determine (at block 718) the zone object 110 a . . . 110n referenced by the fabric object representing the selected zone. A determination is then made (at block 720) of all graph nodes 106a . . . 106n referenced by the determined zone object 110a . . . 110n, in field 212 (FIG. 8), which represent switch ports in the selected zone. The graph interface 46 then renders (at block 722) all SAN components connected to switch ports represented by determined graph nodes 106a . . . 106n referenced by the determined zone object 110a . . . 110n in a different manner than SAN components connected to switch ports that are not referenced by the determined zone object. For instance, in the output 650 in FIG. 18, the components 652b, 652c, switch 654b, and storage 656a, 656b, 656d within the selected zone are rendered in a different manner than the components 652a, 654a, 656c outside of the selected zone. Alternatively, if no zone was selected when the graph interface 42 was invoked, then all the host, switch, and storage components in the selected fabric would be rendered in the same manner, without zone distinctions.

In additional implementations, the graph interface 46 may include GUI panels, such as a user interface wizard, to allow a user to select a host 6a, 6b, 6c (FIG. 1) and storage 10a, 10b, 10c in the SAN 2, and then automatically show all switches that connect, either directly or indirectly, to the selected host and storage. This allows the user or SAN administrator to determine whether the selected SAN components are physically and logically connected. Further, by displaying information on all switches connected to each selected component, the administrator can determine which connections to add between a switch connected, directly or indirectly (i.e., through cascading) to one selected component and the other component or a switch to which the other component is connected. Further implementations display zone information to allow the administrator to determine whether the assignment of switch ports to zones needs to be altered to provide a connection between the selected host and storage.

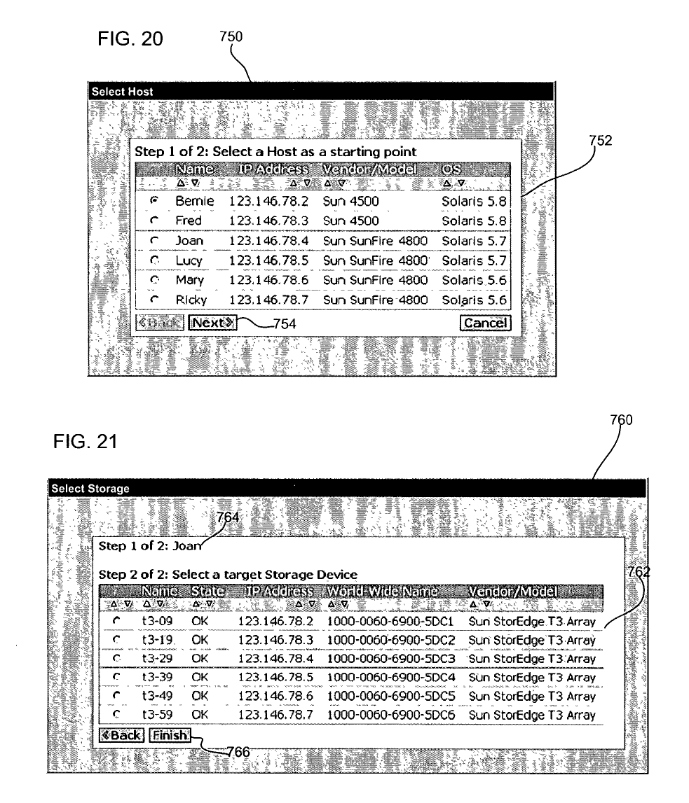

FIGS. 20, 21, and 22 illustrate the GUI panels presented to the user to gather information on selected devices and then display the switches directly and indirectly connected to the user selected devices. FIG. 20 illustrates a GUI panel 750 that the graph interface 46 renders in a display monitor attached to the SAN management system 30 (FIG. 2) that displays a list 752 of all the hosts 6a, 6b, 6c (FIG. 1) in the SAN 2. Alternatively, the user may manually enter the name of a host to select. Upon selecting the “Next” button 754, the graph interface 46 displays GUI panel 760 shown in FIG. 21 that displays a list 762 of storages 10a, 10b, 10c (FIG. 1) from which the user may select. The panel 760 further displays the name of the host 764 the user selected in the previous panel 750. Selection of the “Next” button 766 would cause the graph interface 46 to display the topology showing all switches directly and indirectly connected to the selected host and storage.

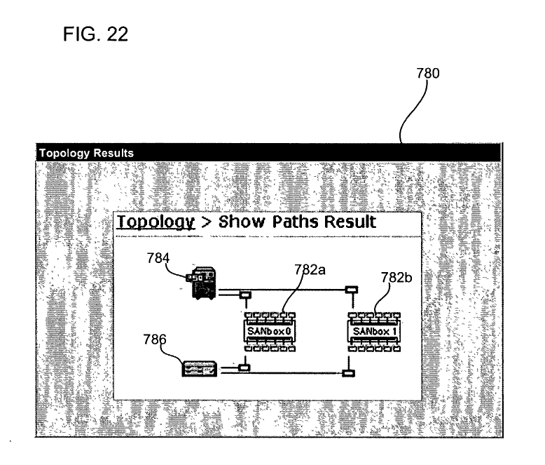

FIG. 22 illustrates an example of a GUI panel 780 showing the switches 782a, 782b to which the selected host 784 and selected storage 786 are attached. In the topology shown in FIG. 22, both selected host and storage are connected directly to the same switches.

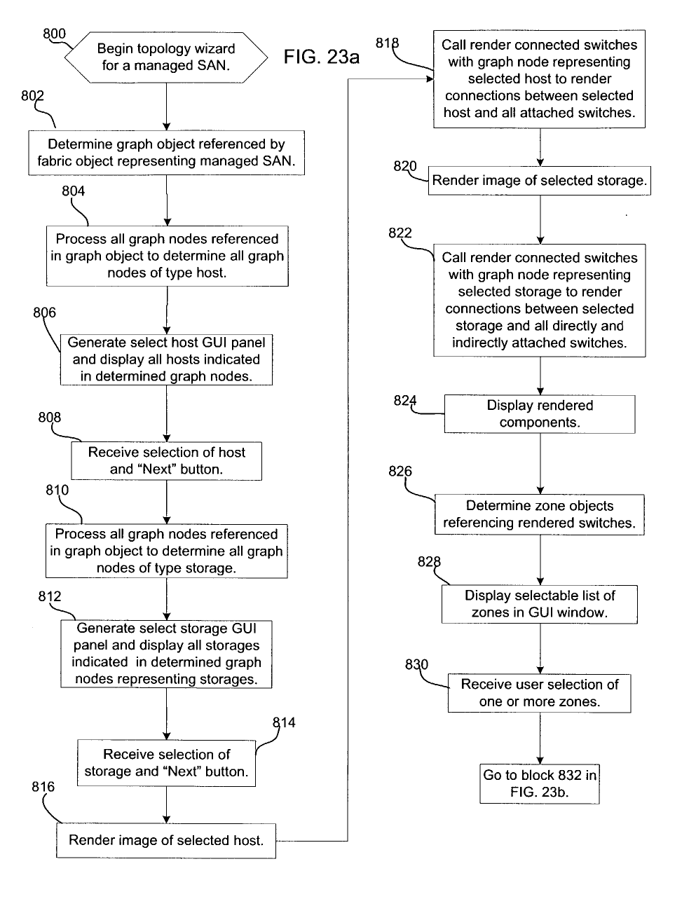

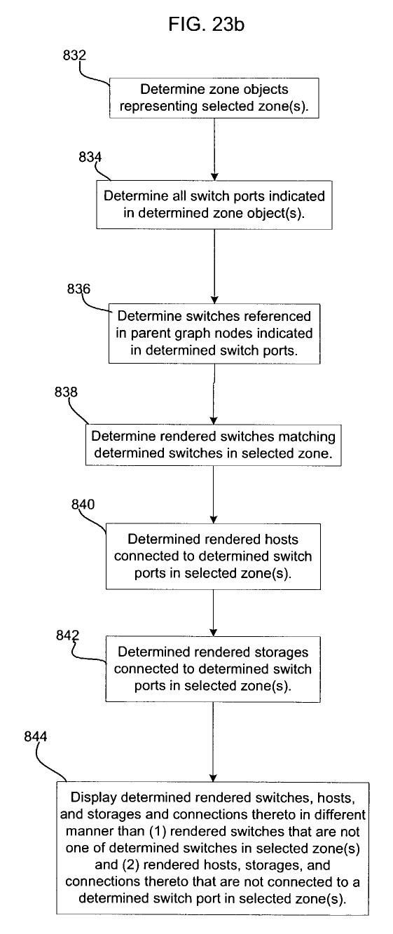

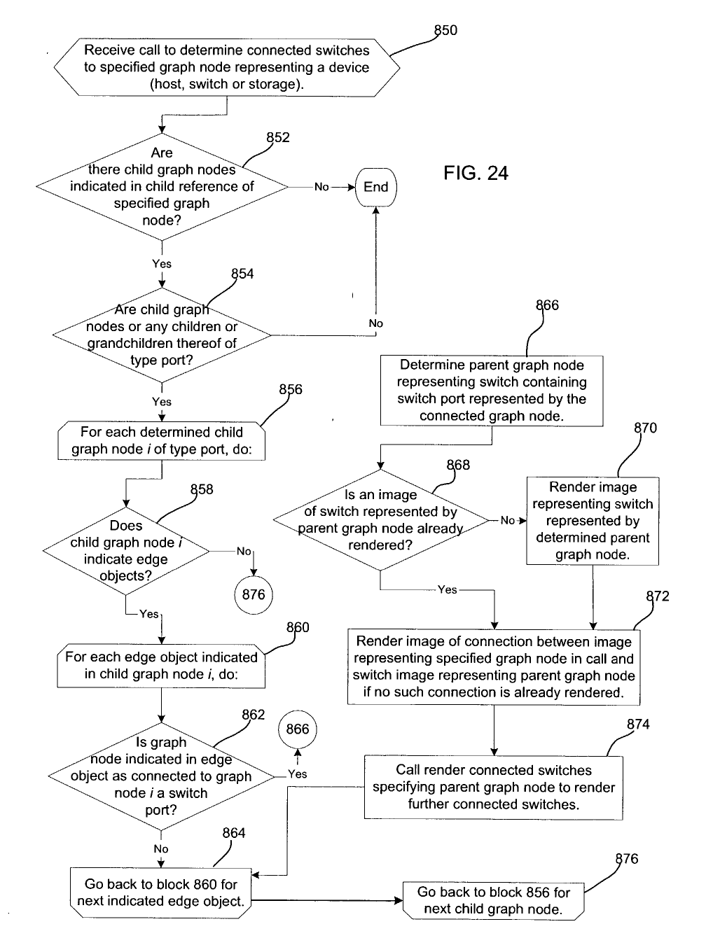

FIGS. 23a, 23b and 24 illustrate logic implemented in the graph interface 46 to display the GUI panels 750 and 760, and generate the topology showing all switches directly and indirectly connected to the selected host and storage. With respect to FIG. 23a, control begins with a call being made (at block 800) to the graph interface 46 to run a topology wizard to allow the user to select a host and storage to represent switch connections therebetween. The graph interface 46 determines (at block 802) the graph object 104 referenced by the fabric object 102a . . . 102n (FIG. 3) representing a specified fabric being considered. All graph nodes 106a . . . 106n referenced by the determined graph object 104 are processed (at block 804) to determine all graph nodes having type (indicated in type field 178 in FIG. 5) host. The graph interface 46 then generates (at block 806) the GUI panel 750 (FIG. 20) showing all hosts represented by the determined graph nodes to enable user selection of any of the determined hosts. Upon receiving (at block 808) user selection of one host and the “Next” button 754 in GUI panel 750, all graph nodes 106a . . . 106n are processed (at block 810) to determine all graph nodes of type storage. The graph interface 46 then renders (at block 812) the select storage GUI panel 760 (FIG. 21) to display a selectable list of all the storage devices represented by the determined storage graph nodes. Upon receiving (at block 814) selection of a storage and the “Next” button 766 (FIG. 21), the graph interface 46 begins the process of processing the graph topology 44 (FIG. 2) objects to render a display of the selected host and storage and all switches connected therebetween, as well as zone information on the storage and switches in the zones the selected host can access.

At block 816, the image of the selected host is rendered. A call is then made (at block 818) to the render connected switches program with the graph node representing the selected host, whose logic is shown in FIG. 24, to render connections between the selected host and any switches connected directly or indirectly to the selected host. The image of the selected storage is rendered (at block 820) and a call is made (at block 822) to the render connected switches program with the graph node representing the selected storage, to render connections between the selected storage and any switches connected directly or indirectly to the selected host. The rendered components are displayed, such as in the manner displayed in FIG. 18 without the indication of the zone in which the components are included.

The graph interface 46 then determines (at block 826) the zone objects 110a . . . 110n referencing the rendered switches, in the reference field 212 of the zone objects and displays (at block 828) a selectable list of the zones represented by the determined zone objects 110a . . . 110n in a GUI window (not shown). Upon receiving (at block 830) a user selection of one or more of the displayed zones, the graph interface 48 control proceeds to block 832 in FIG. 23b where the graph interface 46 determines zone objects 110a . . . 110n representing selected zone(s). All switch ports referenced in the determined zone object(s) 110a . . . 110n are determined (at block 834), from field 212 (FIG. 8) in the zone objects 110a . . . 110n. A determination is then made (at block 836) of all switches referenced in the parent field 172 (FIG. 5) of the graph objects for the determined switch ports in the selected zone(s). The graph interface 46 further determines (at block 838) all switches matching the determined switches in selected zone(s). All the hosts and storages connected to switch ports in the selected zone(s) are determined (at block 840 and 842). The graph interface 46 then renders (at block 844) switches, hosts and storages and connections thereto in different manner than both (1) rendered switches that are not one of the determined switches in the selected zone(s) and (2) rendered hosts, storages and connections thereto that are not connected to determined switch ports in selected zone(s).

FIG. 24 illustrates the logic executed when a call is made (at block 850) to the render connected switches program to a switch, host or storage represented by the graph node included with the call. If (at block 852) there are child graph nodes indicated in the child reference field 174 (FIG. 5) of the graph node specified in the call and if (at block 854) any of the child graph nodes or further children thereof represent a port component, as indicated in the node type field 178, then a loop is performed at blocks 856 through 876 to render images of any connected switches to any determined child graph nodes i representing ports contained in the device represented by the parent node. Otherwise if there are no ports contained in the device represented by the specified graph node, then control ends. If (at block 858) the child graph node i fields 180 and 182 reference edge objects 108a . . . 108n, then for each referenced edge object (at blocks 860-864) a determination is made (at block 862) as to whether the graph node indicated in the edge object as connected to graph node i is a switch port. If so, a determination is made (at block 866) of the parent graph node representing the switch containing the switch port represented by the connected graph node (which would be indicated in the parent field 172 (FIG. 5) of the connected graph node). If (at block 868) an image of a switch represented by the determined parent graph node is not already rendered, then an image of the switch is rendered (at block 870). From the yes branch of block 868 or block 870, control proceeds to block 872 to render an image of a connection between the image representing the specified graph node in the call, which may represent a host, storage or switch, and the switch image representing the determined parent graph node if no such connection is already rendered. Alternatively, if there are two cables between two devices, then an image of both those cables may be rendered. The routine would further make a nested call (at block 874) to the render connected switches routine specifying the parent graph node representing the switch just rendered to render any cascading switches connected to the just rendered switch. In this way, the render connected switches routine recursively renders all switches including switch ports that connect directly or indirectly to the selected host and storage.

After rendering representations of the connections to switches directly and indirectly to the selected host and storage, the graph interface 46 determines (at block 824) all the zones belonging to the fabrics whose switches have been rendered and determines (at block 826) the zone objects 110a . . . 110n representing the determined zone(s). A determination is then made (at block 828) of all switch ports, represented by nodes 106i . . . 106m or 106j . . . 106p in the determined zone object(s) 110a . . . 110n, and a determination is made (at block 830) of the switches represented by parent graph nodes indicated in the parent field 172 (FIG. 5) of the graph nodes referenced in the determined zone object(s). Any rendered switches matching the determined switches are displayed (at blocks 832 and 834) in a different manner than switches that are not in the determined zone(s), i.e., switches having switch ports not referenced in the determined zone objects. For instance, the switches not in the zones accessible to the selected host may be displayed in a lighter shade then the switches and connections within the zone(s) that includes the host.

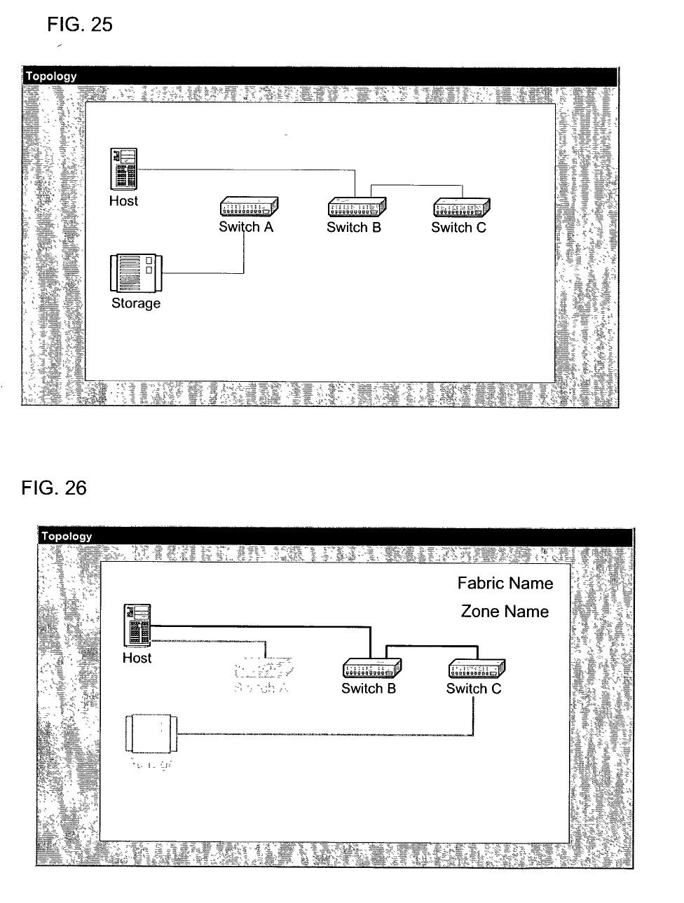

FIG. 25 illustrates an example of a topology rendered according to the logic of FIGS. 23a, 23b and 24. The topology shows all switches to which a selected host and storage connect, both indirectly or directly. The topology shown in FIG. 25 may indicate that all the connected paths and switches are in zone(s) accessible to the host because they are rendered in the same manner, e.g., with the same degree of boldness. FIG. 26 illustrates a further example where some of the connected switches and path to the selected host are displayed in a different manner than other paths connected to the host, indicating that switch A and the selected storage are in zones inaccessible to the host, whereas the switch ports in switches B and C that connect to the host are in the same zone as the host, whereas the storage connects on a path to a switch port in switch C that is in a zone inaccessible to the host. Those paths and devices in zones not accessible to the host are rendered in a lighter shade than those paths and components in zones accessible to the host. The rendered connections may further indicate the fabric name and zone name including the rendered components.

In further implementations, the user may select multiple hosts and storage in the GUI panels to render switches connected to all the selected hosts and storages.

The above described logic for rendering a view of all switches connected to a selected host and storage allow the user to easily determine how to provide further connection paths between the host and storage. For instance, the user can determine that if no path provides a common connection, then a connection can be made from one device to a switch having switch ports to which the other device connects. Alternatively, if the devices share a common switch, but the selected host and storage are in different zones as shown in FIG. 26, then the user can decide to reconfigure the switch ports connecting the devices to the common switch to be in the same zone to provide a path between the selected host and storage. The above topology may further be used for failure analysis to determine whether there is no single point of failure in the connections between a selected host and storage. If there are single points of failure, then the administrator may add additional switches or connections from the selected host and/or storage to the existing switches to enhance the availability of the selected host and storage.

Numerous other algorithms and techniques may be used to traverse the nodes in the graph topology 44 to determine any level of component, e.g., port, adaptor, storage, host, switch, within any fabric in the SAN. Further, upon displaying composite components at one level, e.g., such as the hosts, switches, and storages shown in FIGS. 17, 21, 24, and 25, selection of a particular composite component may cause the rendering of subcomponents within a selected composite component by accessing child references in the graph node representing the selected composite component. For instance, selection of a host may cause the graph interface 46 to render information on host bus adaptor (HBA) components and ports therein by traversing the children graph nodes, representing HBAs, of the graph node representing the selected composite host, and then traversing the children graph nodes of the HBA graph node representing ports.

Numerous other functions may be used to traverse the object topology to access and render information at any level of the topology.

### Additional Implementation Details

The described techniques for maintaining information on network components may be implemented as a method, apparatus or article of manufacture using standard programming and/or engineering techniques to produce software, firmware, hardware, or any combination thereof. The term “article of manufacture” as used herein refers to code or logic implemented in hardware logic (e.g., an integrated circuit chip, Programmable Gate Array (PGA), Application Specific Integrated Circuit (ASIC), etc.) or a computer readable medium, such as magnetic storage medium (e.g., hard disk drives, floppy disks, tape, etc.), optical storage (CD-ROMs, optical disks, etc.), volatile and non-volatile memory devices (e.g., EEPROMs, ROMs, PROMs, RAMs, DRAMs, SRAMs, firmware, programmable logic, etc.). Code in the computer readable medium is accessed and executed by a processor. The code in which preferred embodiments are implemented may further be accessible through a transmission media or from a file server over a network. In such cases, the article of manufacture in which the code is implemented may comprise a transmission media, such as a network transmission line, wireless transmission media, signals propagating through space, radio waves, infrared signals, etc. Of course, those skilled in the art will recognize that many modifications may be made to this configuration without departing from the scope of the present invention, and that the article of manufacture may comprise any information bearing medium known in the art.

The described implementations discussed maintaining information on components within a SAN. However, those skilled in the art will appreciate that the device management techniques described herein may be utilized to maintain information on components within any network environment known in the art.

The described implementations provided a topology and object architecture for maintaining information on different components in a SAN network. An alternative object architecture may be provided, such that component information described as included in different objects may be merged in a single object or component information described as included in a single object may be distributed across multiple objects.

The illustrated logic of FIGS. 10-17 and 19 shows certain events occurring in a certain order. In alternative implementations, certain operations may be performed in a different order, modified or removed. Morever, steps may be added to the above described logic and still conform to the described implementations. Further, operations described herein may occur sequentially or certain operations may be processed in parallel. Yet further, operations may be performed by a single processing unit or by distributed processing units.

FIG. 20 illustrates one implementation of a computer architecture 800 of the SAN components and systems shown in FIGS. 1 and 2. The architecture 800 may include a processor 802 (e.g., a microprocessor), a memory 804 (e.g., a volatile memory device), and storage 806 (e.g., a non-volatile storage, such as magnetic disk drives, optical disk drives, a tape drive, etc.). The storage 806 may comprise an internal storage device or an attached or network accessible storage. Programs in the storage 806 are loaded into the memory 804 and executed by the processor 802 in a manner known in the art. The architecture further includes a network card 808 to enable communication with a network. An input device 810 is used to provide user input to the processor 802, and may include a keyboard, mouse, pen-stylus, microphone, touch sensitive display screen, or any other activation or input mechanism known in the art. An output device 812 is capable of rendering information transmitted from the processor 802, or other component, such as a display monitor, printer, storage, etc. The illustrated logic of FIGS. 10-17, 19, 23a, 23b, and 24 shows certain events occurring in a certain order. In alternative implementations, certain operations may be performed in a different order, modified or removed. Morever, steps may be added to the above described logic and still conform to the described implementations. Further, operations described herein may occur sequentially or certain operations may be processed in parallel. Yet further, operations may be performed by a single processing unit or by distributed processing units.

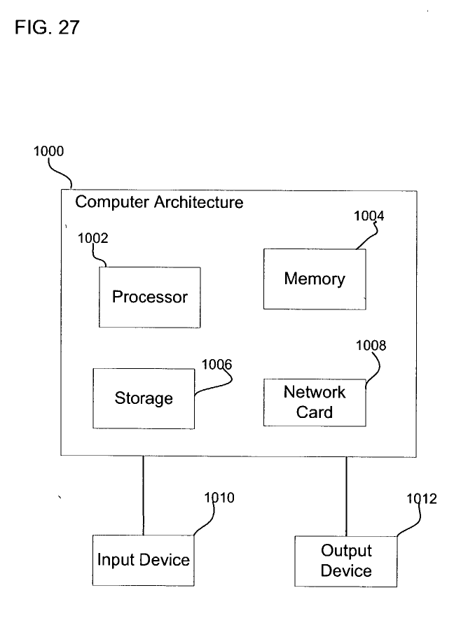

FIG. 27 illustrates one implementation of a computer architecture 1000 of the SAN components and systems shown in FIGS. 1 and 2. The architecture 1000 may include a processor 1002 (e.g., a microprocessor), a memory 1004 (e.g., a volatile memory device), and storage 1006 (e.g., a non-volatile storage, such as magnetic disk drives, optical disk drives, a tape drive, etc.). The storage 1006 may comprise an internal storage device or an attached or network accessible storage. Programs in the storage 1006 are loaded into the memory 1004 and executed by the processor 1002 in a manner known in the art. The architecture further includes a network card 1008 to enable communication with a network. An input device 1010 is used to provide user input to the processor 1002, and may include a keyboard, mouse, pen-stylus, microphone, touch sensitive display screen, or any other activation or input mechanism known in the art. An output device 1012 is capable of rendering information transmitted from the processor 1002, or other component, such as a display monitor, printer, storage, etc.

The foregoing description of various implementations of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. A method for providing information on components within a network, comprising:
receiving a user selected host and storage in the network;
determining switches to which the selected host and storage connect; and
rendering images representing the selected host and storage and all determined switches and connections therebetween.

2. The method of claim 1, further comprising:
determining at least one zone; and
rendering the images representing components in the determined at least one zone in a different manner than images representing components not in the determined at least one zone.

3. The method of claim 2, further comprising:
determining all zones in which the components representing the rendered images are included;
displaying a selectable list of all determined zones; and
receiving user selection of at least one zone, wherein the determined at least one zone comprises the at least one user selected zone.

4. The method of claim 1, further comprising:
determining hosts in the network; and
generating a user interface listing the determined hosts, wherein indication of the user selected host is received through the generated user interface.

5. The method of claim 4, further comprising:
determining storage systems in the network; and
generating a user interface listing the determined storage systems, wherein indication of the user selected storage is received through the generated user interface.

6. The method of claim 1, wherein determining the switches comprises determining all switches to which the selected host and storage directly and indirectly connect, and wherein the switches directly and indirectly attached and connections thereto are rendered.

7. The method of claim 1, further comprising:
providing component objects representing the interconnected components including switches, hosts, and storages, wherein at least one object represents a device component including at least one port, wherein each port component is represented by one port object, wherein relationship information indicates a relationship between each device object and the port objects representing ports included in the device;
determining the device objects representing the selected host and storage; and
determining the port objects related to the determined device objects, wherein determining the switches comprises determining switches having switch ports that connect directly or indirectly to the host and storage ports represented by the determined port objects.

8. The method of claim 7, further comprising:
providing connection information for each port represented by one port object indicating a remote port to which the port connects, wherein determining the switches further comprises:
(i) processing the connection information for the determined host and storage port objects to determine switch ports to which the determined host and storage ports connect; and
(ii) determining at least one device object representing at least one switch including the determined switch ports, wherein the determined switches are represented by the determined at least one device object representing the at least one switch.

9. The method of claim 8, wherein determining the switches further comprises:
for each determined device object representing one switch, processing the connection information for the device object to determine additional device objects representing additional switches having switch ports connected to the switch ports of the determined device object.

10. The method of claim 1, further comprising:
determining at least one path from the selected host to at least one direct attached storage; and
rendering images representing the determined at least one path to the at least one direct attached storage.

11. The method of claim 1, wherein the rendered images representing the selected host, storage, and all determined switches connected to the host and storage do not show any common switch providing an interconnection between the host and storage.

12. The method of claim 1, wherein the rendered images show a switch providing a physical connection between the selected host and storage and wherein the rendered images do not show any interconnection between the host and storage by representing the physical connection between the selected host and storage as included in a zone inaccessible to the selected host.

13. A system for providing information on components within a network, comprising:
means for receiving a user selected host and storage in the network;
means for determining switches to which the selected host and storage connect; and
means for rendering images representing the selected host and storage and all determined switches and connections therebetween.

14. The system of claim 13, further comprising:
means for determining at least one zone; and
means for rendering the images representing components in the determined at least one zone in a different manner than images representing components not in the determined at least one zone.

15. The system of claim 14, further comprising:
means for determining all zones in which the components representing the rendered images are included;
means for displaying a selectable list of all determined zones; and
means for receiving user selection of at least one zone, wherein the determined at least one zone comprises the at least one user selected zone.

16. The system of claim 13, wherein the means for determining the switches determines all switches to which the selected host and storage directly and indirectly connect, and wherein the switches directly and indirectly attached and connections thereto are rendered.

17. The system of claim 13, further comprising:
means for providing component objects representing the interconnected components including switches, hosts, and storages, wherein at least one object represents a device component including at least one port, wherein each port component is represented by one port object, wherein relationship information indicates a relationship between each device object and the port objects representing ports included in the device;
determining the device objects representing the selected host and storage; and
determining the port objects related to the determined device objects, wherein determining the switches comprises determining switches having switch ports that connect directly or indirectly to the host and storage ports represented by the determined port objects.

18. The system of claim 13, further comprising:
means for determining at least one path from the selected host to at least one direct attached storage; and
means for rendering images representing the determined at least one pat to the at least one direct attached storage.

19. The system of claim 13, wherein the means for rendered images representing the selected host, storage, and all determined switches connected to the host and storage does not show any common switch providing an interconnection between the host and storage.

20. The system of claim 13, wherein the rendered images show a switch providing a physical connection between the selected host and storage and wherein the rendered images do not show any interconnection between the host and storage by representing the physical connection between the selected host and storage as included in a zone inaccessible to the selected host.

21. A system for providing information, comprising:
a network;
a plurality of network components;
means for receiving a user selected host and storage in the network;
means for determining switches to which the selected host and storage connect; and
means for rendering images representing the selected host and storage and all determined switches and connections therebetween.

22. The system of claim 21, further comprising:
means for determining at least one zone; and
means for rendering the images representing components in the determined at least one zone in a different manner than images representing components not in the determined at least one zone.

23. The system of claim 21, wherein the means for determining the switches determines all switches to which the selected host and storage directly and indirectly connect, and wherein the switches directly and indirectly attached and connections thereto are rendered.

24. The system of claim 21, further comprising:
means for determining at least one path from the selected host to at least one direct attached storage; and
means for rendering images representing the determined at least one pat to the at least one direct attached storage.

25. An article of manufacture for providing information on components within a network, wherein the article of manufacture is comprising:
receiving a user selected host and storage in the network;
determining switches to which the selected host and storage connect; and
rendering images representing the selected host and storage and all determined switches and connections therebetween.

26. The article of manufacture of claim 25, further comprising:
determining at least one zone; and
rendering the images representing components in the determined at least one zone in a different manner than images representing components not in the determined at least one zone.

27. The article of manufacture of claim 26, further comprising:
determining all zones in which the components representing the rendered images are included;
displaying a selectable list of all determined zones; and
receiving user selection of at least one zone, wherein the determined at least one zone comprises the at least one user selected zone.

28. The article of manufacture of claim 25, further comprising:
determining hosts in the network; and
generating a user interface listing the determined hosts, wherein indication of the user selected host is received through the generated user interface.

29. The article of manufacture of claim 28, further comprising:
determining storage systems in the network; and
generating a user interface listing the determined storage systems, wherein indication of the user selected storage is received through the generated user interface.

30. The article of manufacture of claim 25, wherein determining the switches comprises determining all switches to which the selected host and storage directly and indirectly connect, and wherein the switches directly and indirectly attached and connections thereto are rendered.

31. The article of manufacture of claim 25, further comprising:
providing component objects representing the interconnected components including switches, hosts, and storages, wherein at least one object represents a device component including at least one port, wherein each port component is represented by one port object, wherein relationship information indicates a relationship between each device object and the port objects representing ports included in the device;
determining the device objects representing the selected host and storage; and
determining the port objects related to the determined device objects, wherein determining the switches comprises determining switches having switch ports that connect directly or indirectly to the host and storage ports represented by the determined port objects.

32. The article of manufacture of claim 31, further comprising:
providing connection information for each port represented by one port object indicating a remote port to which the port connects, wherein determining the switches further comprises:
(i) processing the connection information for the determined host and storage port objects to determine switch ports to which the determined host and storage ports connect; and
(ii) determining at least one device object representing at least one switch including the determined switch ports, wherein the determined switches are represented by the determined at least one device object representing the at least one switch.

33. The article of manufacture of claim 32, wherein determining the switches further comprises:
for each determined device object representing one switch, processing the connection information for the device object to determine additional device objects representing additional switches having switch ports connected to the switch ports of the determined device object.

34. The article of manufacture of claim 25, further comprising:
determining at least one path from the selected host to at least one direct attached storage; and
rendering images representing the determined at least one path to the at least one direct attached storage.

35. The article of manufacture of claim 25, wherein the rendered images representing the selected host, storage, and all determined switches connected to the host and storage do not show any common switch providing an interconnection between the host and storage.

36. The article of manufacture of claim 25, wherein the rendered images show a switch providing a physical connection between the selected host and storage and wherein the rendered images do not show any interconnection between the host and storage by representing the physical connection between the selected host and storage as included in a zone inaccessible to the selected host.
